(19) United States
(12) Patent Application Publication
(10) Pub. No.: US 2026/0287919 A1
(43) Pub. Date: Sep. 24, 2026

(54) TRANSPARENT DISPLAY AND SWITCHABLE 2D/3D TRANSPARENT DISPLAY

(71) Applicant: AUO Corporation, Hsinchu City (TW)

(72) Inventors: Jia-Hong Wang, Hsinchu City (TW); Ya-Ling Hsu, Hsinchu City (TW); Chen-Hsien Liao, Hsinchu City (TW)

(73) Assignee: AUO Corporation, Hsinchu City (TW)

(21) Appl. No.: 19/304,615

(22) Filed: Aug. 20, 2025

(30) Foreign Application Priority Data
Mar. 20, 2025 (TW) 114110436

(51) Int. Cl. G02B 30/28; G02F 1/1333; G02F 1/1343; H10H 29/855

(52) U.S. Cl. CPC G02B 30/28; G02F 1/133377; G02F 1/13439; H10H 29/855

(57) ABSTRACT

A transparent display including a plurality of pixels is provided. Each of the pixels includes a first substrate, a plurality of light-emitting elements, an optical layer, and an optical modulation layer. The light-emitting elements are disposed on the first substrate and located in an active luminous area of the pixel. The optical layer directly covers the light-emitting elements and a refractive index of the optical layer is greater than 1. The optical modulation layer is disposed on the optical layer. A switchable 2D/3D transparent display is also provided.

### CROSS-REFERENCE TO RELATED APPLICATION

This application claims the priority benefit of Taiwan application serial no. 114110436, filed on March 20, 2025. The entirety of the above-mentioned patent application is hereby incorporated by reference herein and made a part of this specification.

### BACKGROUND OF THE INVENTION

### FIELD OF THE INVENTION

The invention relates to a display, and more particularly to a transparent display and a switchable 2D/3D transparent display.

### DESCRIPTION OF RELATED ART

3D displays on the market all aim to attract purchase from consumers via the feature of a plurality of depths of field thereof. Transparent 3D LCDs are a good option for providing a more immersive experience. However, the transmittance of existing transparent 3D LCDs is insufficient, making existing transparent 3D LCDs ineffective in integrating with the surrounding environment.

### SUMMARY OF THE INVENTION

The invention provides a transparent display and a switchable 2D/3D transparent display with high transparency.

According to an embodiment of the invention, a transparent display is provided, including a plurality of pixels. Each of the pixels includes a first substrate, a plurality of light-emitting elements, an optical layer, and an optical modulation layer. The light-emitting elements are disposed on the first substrate and located in an active luminous area of the pixel. The optical layer directly covers the light-emitting elements, and a refractive index of the optical layer is greater than 1. The optical modulation layer is disposed on the optical layer.

According to an embodiment of the invention, a switchable 2D/3D transparent display is provided, including the transparent display.

Based on the above, the transparent display and the switchable 2D/3D transparent display provided by an embodiment of the invention directly cover the light-emitting elements via the optical layer to improve light extraction efficiency. Furthermore, by using the optical modulation layer, the transparent display may be implemented as a 3D transparent display and a 2D transparent display.

In order to make the above features and advantages of the invention more clearly understood, embodiments are given below and described in detail with reference to the accompanying drawings.

### BRIEF DESCRIPTION OF THE DRAWINGS

FIG. 1 shows a schematic plan view of a transparent display according to some embodiments of the invention.

FIG. 2 shows a partial cross-sectional view along line AA’ of FIG. 1 according to the first embodiment of the invention.

FIG. 3 shows a partial cross-sectional view of a transparent display according to the second embodiment of the invention.

FIG. 4 shows a partial cross-sectional view of a transparent display according to the third embodiment of the invention.

### DESCRIPTION OF THE EMBODIMENTS

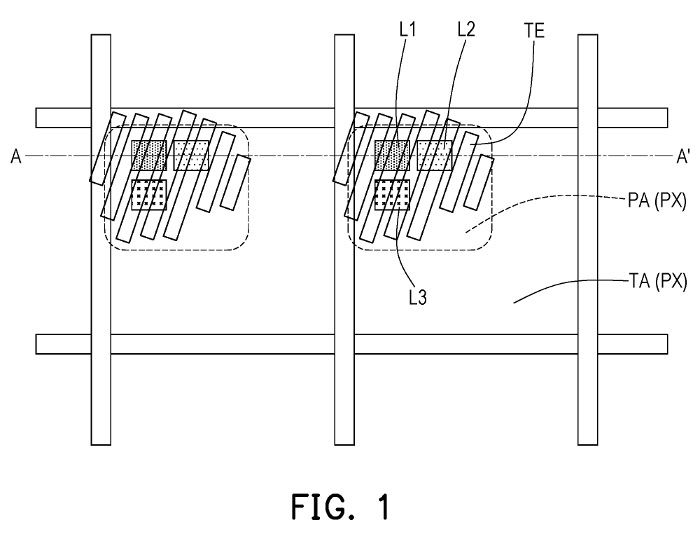

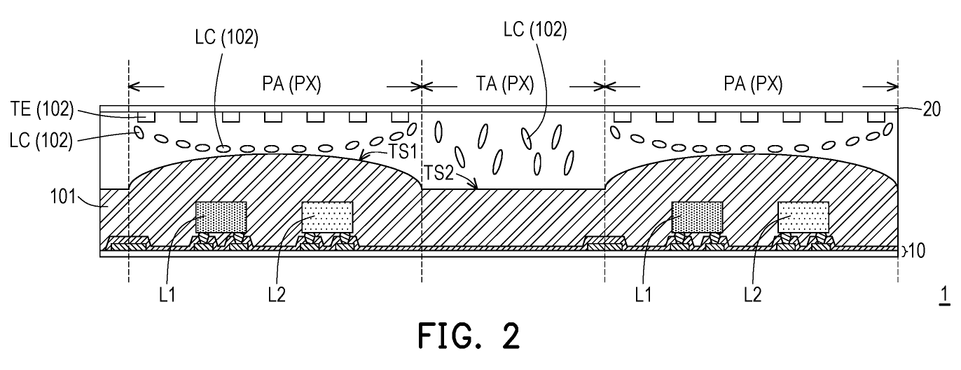

Referring to FIG. 1 and FIG. 2, FIG. 1 shows a schematic plan view of a transparent display according to some embodiments of the invention, and FIG. 2 shows a partial cross-sectional view along line AA’ of FIG. 1 according to the first embodiment of the invention.

A transparent display 1 according to the first embodiment includes a plurality of pixels PX. Each of the pixels PX includes a substrate 10, a substrate 20, light-emitting elements L1, L2, and L3, an optical layer 101, and an optical modulation layer 102. The light-emitting elements L1, L2, and L3 are disposed in an active luminous area PA of the pixel PX. Each of the pixels PX also has a transparent area TA in which no light-emitting elements are disposed. In some embodiments, the light-emitting elements L1, L2, and L3 may include one red micro-LED, one green micro-LED, and one blue micro-LED, but is not limited thereto.

The refractive index of the optical layer 101 is greater than 1 and the optical layer 101 directly covers the light-emitting elements L1, L2, and L3. Light emitted by the light-emitting elements L1, L2, and L3 may directly enter the optical layer 101. The optical modulation layer 102 is disposed on optical layer 101 and used to modulate the light emitted by the light-emitting elements L1, L2, and L3. This modulation, for example, refers to phase modulation, such that the image of the transparent display 1 may be changed. In some embodiments, the optical layer 101 may include polyester film, polyimide, fluoropolymer, epoxy resin, and the like, but is not limited thereto.

Specifically, in some embodiments, the optical modulation layer 102 may include a liquid-crystal layer and a transparent electrode layer TE, wherein the liquid-crystal layer includes a plurality of liquid-crystal molecules LC. By applying voltage to the liquid-crystal molecules LC via the transparent electrode layer TE, the long axis direction of each of the liquid-crystal molecules LC may be controlled, achieving a modulation function. Therefore, depending on the applied voltage, the transparent display 1 may be implemented as a 3D transparent display and a 2D transparent display, switching between the 3D transparent display and the 2D transparent display to produce a 3D image or a 2D image. Therefore, in some embodiments, the transparent display 1 is suitable for being implemented as a switchable 2D/3D transparent display.

In the structure shown in FIG. 2, to improve the brightness of the transparent display 1 at a normal viewing angle, a top surface TS1 of the optical layer 101 at the active luminous area PA may be configured as a convex surface (i.e., curved surface), and the convex surface is used to provide a refractive effect. With this configuration, the optical paths of the light from the light-emitting elements L1, L2, and L3 and traveling in different directions may be different in the optical layer 101. The optical path difference may be compensated by applying a specific electric field at the liquid-crystal layer.

It should be noted that, compared to the prior art, where the optical layer 101 is disposed in a module above the light-emitting elements L1, L2, and L3, the optical layer 101 of the first embodiment is configured to directly cover the light-emitting elements L1, L2, and L3. Accordingly, light emitted by the light-emitting elements L1, L2, and L3 may directly enter the optical layer 101, preventing light at one or a plurality of boundary surfaces of the module from being reflected and improving light extraction efficiency. Similarly, the optical modulation layer 102 is directly in contact with the optical layer 101, and light penetrating the optical layer 101 may directly enter the optical modulation layer 102.

In some embodiments, the refractive index of the optical layer 101 is configured to be greater than the refractive index of the optical modulation layer 102, and the refractive index of the optical modulation layer 102 is greater than 1 (but not limited thereto). Accordingly, light from the light-emitting elements L1, L2, and L3 may sequentially pass through the optical layer 101 for which refractive index is gradually decreased, the optical modulation layer 102, and the air layer above the substrate 20, where the refractive index of the air layer is approximately 1. Therefore, total internal reflection at the interfaces between the different media may be prevented.

In the first embodiment shown in FIG. 2, the area ratio of the transparent area TA to the active luminous area PA of each of the pixels PX is greater than or equal to 1.5. In other words, the active luminous area PA of each of the pixels PX has a first area, and the transparent area TA of each of the pixels PX has a second area, wherein the ratio of the second area to the sum of the first area and the second area is greater than or equal to 60%. Therefore, the transparency of the transparent display 1 may be high.

In the first embodiment, the optical layer 101 of each of the pixels PX is disposed in the active luminous area PA and disposed in the transparent area TA. To improve the transparency of the transparent display 1, the thickness of the optical layer 101 in the transparent area TA may be less than the thickness of the optical layer 101 in the active luminous area PA. Furthermore, since the optical layer 101 in the transparent area TA does not need to provide a refractive function, a top surface TS2 of the optical layer 101 in the transparent area TA may be a flat surface (as shown in FIG. 2). Therefore, the manufacturing difficulty of the transparent display 1 may be reduced, but is not limited thereto.

In order to fully illustrate the various embodiments of the invention, other embodiments of the invention are described below. It should be noted that the following embodiments adopt the reference numerals and some of the content of the previous embodiments, wherein the same reference numerals are adopted to represent the same or similar elements, and the description of the same technical content is omitted. For the description of the omitted portions, please refer to the previous embodiments, which are not repeated in the following embodiments.

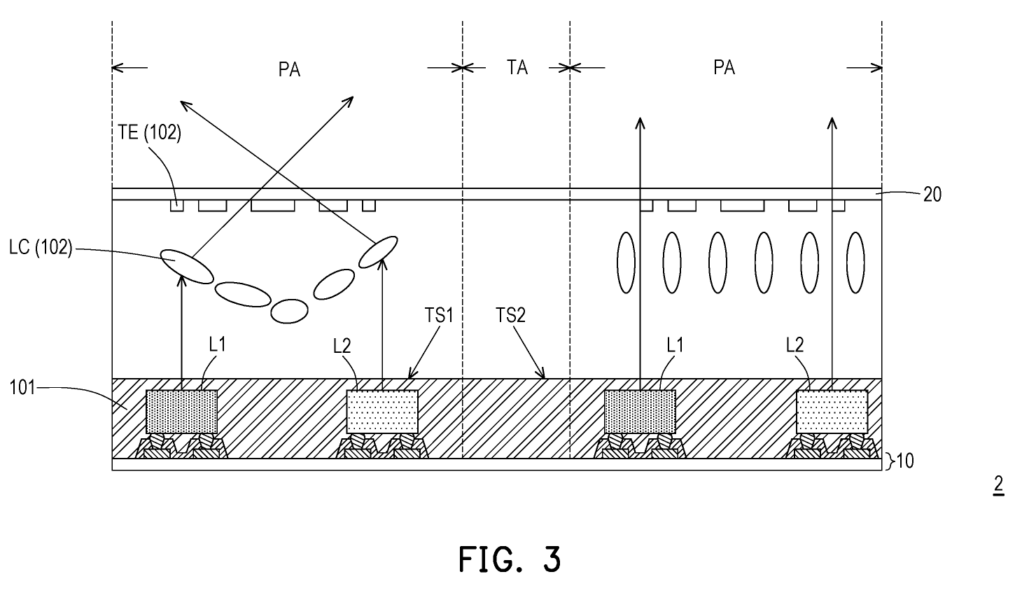

FIG. 3 shows a partial cross-sectional view of a transparent display according to the second embodiment of the invention.

A transparent display 2 of the second embodiment of the invention differs primarily from the transparent display 1 of the first embodiment in that a top surface TS1 of the optical layer 101 at the active luminous area PA and a top surface TS2 of the optical layer 101 at the transparent area TA are both flat surfaces, and the two top surfaces TS1 and TS2 are coplanar, and therefore the manufacturing complexity of the transparent display 2 may be reduced. Furthermore, as shown in FIG. 3, the plurality of transparent electrodes of the transparent electrode layer TE may have different widths. In an embodiment not shown, the plurality of transparent electrodes of the transparent electrode layer TE may have the same width, but the distances between two adjacent transparent electrodes may be different.

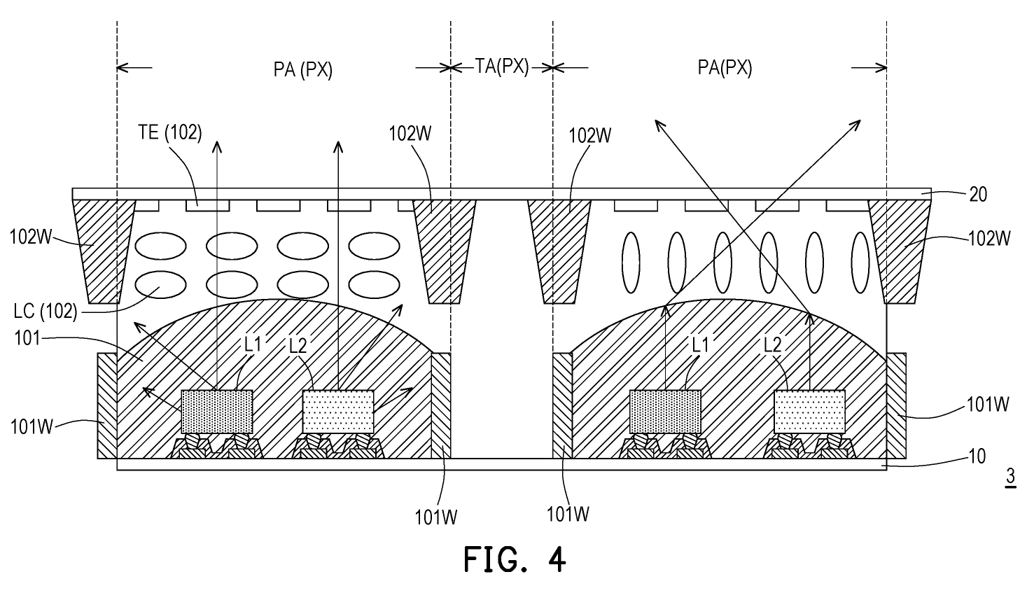

FIG. 4 shows a partial cross-sectional view of a transparent display according to the third embodiment of the invention.

A transparent display 3 of the third embodiment of the invention differs primarily from the transparent display 1 of the first embodiment in that the optical layer 101 of each of the pixels PX is disposed in the active luminous area PA but not disposed in the transparent area TA. That is, the substrate 10 is exposed by the optical layer 101 in the transparent area TA, and the vertical projection area of the optical layer 101 in the transparent area TA is zero. Therefore, the transparency of the transparent display 3 may be improved.

Each of the pixels PX of the transparent display 3 further includes a first retaining wall structure 101W and a second retaining wall structure 102W. The first retaining wall structure 101W is disposed on the substrate 10 and completely surrounds the optical layer 101 covering the light-emitting elements L1, L2, and L3.

The second retaining wall structure 102W is disposed on the substrate 20, completely surrounds the transparent electrode layer TE corresponding to the optical layer 101, and corresponds to the first retaining wall structure 101W, thereby reducing stray light scattering.

Based on the above, the transparent display provided by an embodiment of the invention directly covers the light-emitting elements via an optical layer, thereby improving light extraction efficiency. In addition, using the optical modulation layer, the transparent display may be implemented as a 3D transparent display or a 2D transparent display.

What is claimed is:

1. A transparent display, comprising a plurality of pixels, each of the pixels comprising:
a first substrate;
a plurality of light-emitting elements disposed on the first substrate and located in an active luminous area of the pixel;
an optical layer directly covering the plurality of light-emitting elements, and a refractive index of the optical layer is greater than 1; and
an optical modulation layer disposed on the optical layer.

2. The transparent display of claim 1, wherein an area ratio of a transparent area of each of the pixels to the active luminous area is greater than or equal to 1.5.

3. The transparent display of claim 1, wherein the active luminous area of each of the pixels has a first area, and a transparent area of each of the pixels has a second area, wherein a ratio of the second area to a sum of the first area and the second area is greater than or equal to 60%.

4. The transparent display of claim 1, wherein the optical modulation layer is in direct contact with the optical layer.

5. The transparent display of claim 1, wherein the refractive index of the optical layer is greater than a refractive index of the optical modulation layer, and the refractive index of the optical modulation layer is greater than 1.

6. The transparent display of claim 1, wherein the optical modulation layer comprises a liquid-crystal layer and a transparent electrode layer, and the liquid-crystal layer is located between the optical layer and the transparent electrode layer.

7. The transparent display of claim 1, wherein the optical layer is a flat surface at a top surface of the active luminous area.

8. The transparent display of claim 1, wherein the first substrate is exposed by the optical layer in a transparent area of the pixel.

9. The transparent display of claim 1, wherein the optical layer of each of the pixels is further configured in a transparent area, and the transparent area is adjacent to the active luminous area.

10. The transparent display of claim 9, wherein the optical layer of each of the pixels has a first thickness at the active luminous area and a second thickness at the transparent area, and the first thickness is not equal to the second thickness.

11. The transparent display of claim 10, wherein the second thickness is less than the first thickness.

12. The transparent display of claim 1, wherein the optical layer of each of the pixels is also disposed in a transparent area, the transparent area is adjacent to the active luminous area, the optical layer has a first top surface at the active luminous area and has a second top surface at the transparent area, the first top surface is a curved surface, and the second top surface is a flat surface.

13. The transparent display of claim 1, wherein each of the pixels further comprises a first retaining wall structure disposed on the first substrate and completely surrounding the optical layer covering the plurality of light-emitting elements.

14. The the transparent display of claim 13, wherein each of the pixels further comprises a second substrate and a second retaining wall structure, wherein the plurality of light-emitting elements, the optical layer, and the optical modulation layer are located between the first substrate and the second substrate, and the second retaining wall structure is disposed on the second substrate and corresponds to the first retaining wall structure.

15. The transparent display of claim 1, wherein the transparent display is used to generate a 2D image and a 3D image.

16. A switchable 2D/3D transparent display, comprising the transparent display of claim 1.
